(19) United States
(12) Patent Application Publication
(10) Pub. No.: US 2026/0217964 A1
(43) Pub. Date: Jul. 30, 2026

(54) THERMOSETTING RESIN COMPOSITION, CURED FILM, AND SOLID-STATE IMAGING DEVICE

(71) Applicant: DONGWOO FINE-CHEM CO., LTD., Iksan-si, Jeollabuk-do (KR)

(72) Inventors: In Ho YU, Iksan-si (KR); Kyeongmuk CHOI, Iksan-si (KR); Young Chul PARK, Iksan-si (KR); Seung Yong LEE, Iksan-si (KR); Hun Pyo HONG, Iksan-si (KR)

(73) Assignee: DONGWOO FINE-CHEM CO., LTD., Iksan-si, Jeollabuk-do (KR)

(21) Appl. No.: 19/146,286

(22) PCT Filed: Jan. 19, 2024
(86) PCT No.: PCT/KR2024/000990

§ 371 Date: Jul. 8, 2025

(30) Foreign Application Priority Data
Jan. 25, 2023 (KR) 10-2023-0009701
Dec. 19, 2023 (KR) 10-2023-0186306

(51) Int. Cl. C08L 39/04; C08J 5/18; C08K 5/17; C08K 5/3447; C08K 5/42; H10F 39/00

(52) U.S. Cl. CPC C08L 39/04; C08J 5/18; C08K 5/17; C08K 5/3447; C08K 5/42; H10F 39/804; H10F 39/8063; C08J 2339/04; C08L 2203/16; C08L 2203/206

(57) ABSTRACT

A thermosetting resin composition containing a binder resin, a thermal initiator, a thermosetting agent, and a solvent is disclosed. The binder resin contains an acrylic copolymer containing a repeating unit having a carbazole group and a repeating unit having a glycidyl group. A cured film formed from the thermosetting resin composition and a solid-state imaging device including the cured film are disclosed. The thermosetting resin composition can be cured within minutes at temperatures below 220° C. to form a cured film having high transmittance and high refractive index properties, excellent flatness and hardness, but no coating stains. In addition, the thermosetting resin composition has excellent stability over time, and dry etching resistance properties favorable for implementation of micro-lens geometries.

### TECHNICAL FIELD

The present disclosure relates to a thermosetting resin composition, a cured film, and a solid-state imaging device, and more specifically to a thermosetting resin composition that can be cured within minutes at temperatures below 220° C. and has high transmittance and high refractive index properties, excellent flatness and hardness, no coating stains, excellent stability over time, and properties favorable for implementation of micro-lens geometries, a cured film formed therefrom, and a solid-state imaging device comprising the same cured film.

### BACKGROUND ART

A solid-state imaging device is a device that converts an image taken through light energy into electrical information, and it may include a color filter under the lens. For example, in the case of a CMOS image sensor (CIS), a fine-pitch color filter patterned with a higher resolution than the color filter corresponding to the pixels of a typical display device is adopted. The color filter of a CIS typically has a coloring pattern of the three primary colors of red (R), green (G), and blue (B), which is responsible for decomposing the transmitted light into three primary colors.

These CIS color filters are equipped with an organic protective film, i.e. an overcoat film, to flatten the steps of the RGB color pattern.

Since the overcoat film is formed directly on the RGB coloring pattern, it is necessary to cure the overcoat film at a low temperature and in a short time to minimize the deterioration of the RGB coloring pattern.

Korean Patent Publication No. 10-2006-0036611 discloses a thermosetting resin composition for forming a protective film comprising a bisphenol A type alcohol and a methacrylate or epoxy derived therefrom; or a phenol, as a crosslinking agent to an acrylic resin containing carboxyl groups or epoxy groups.

However, the above thermosetting resin composition has a problem that it is required to be cured at 220° C. for tens of minutes.

Therefore, there is a need to develop a thermosetting resin composition that can be cured at a low temperature in a short time.

In addition, there is a need to develop a thermosetting resin composition that has high transmittance and high refractive index properties, excellent flatness and hardness, and no coating stains when cured to be suitable for overcoat films.

Meanwhile, a micro-lens is formed on the overcoat film that concentrates the incident light to the center to improve the CIS efficiency. Therefore, there is a need for a thermosetting resin composition for forming an overcoat film that exhibits properties favorable to the formation of a micro-lens.

Furthermore, the thermosetting resin composition is required to have stability over time, that is, no change in composition even when stored for a long period of time.

### DISCLOSURE

### Technical Problem

An object of the present disclosure is to provide a thermosetting resin composition that can be cured within minutes at temperatures below 220° C. and has high transmittance and high refractive index properties, excellent flatness and hardness, no coating stains, excellent stability over time, and properties favorable for implementation of micro-lens geometries.

Another object of the present invention is to provide a cured film formed from the above thermosetting resin composition.

Yet another object of the present invention is to provide a solid-state imaging device comprising the above cured film.

### Technical Solution

One aspect of the present invention relates to a thermosetting resin composition comprising a binder resin, a thermal initiator, a thermosetting agent, and a solvent,
wherein the binder resin comprises an acrylic copolymer comprising a repeating unit having a carbazole group and a repeating unit having a glycidyl group.

In one embodiment of the present invention, the repeating unit having a carbazole group may be represented by the following formula (1).

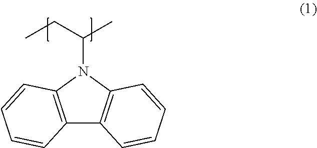

In one embodiment of the present invention, the repeating unit having a glycidyl group may be represented by the following formula (2).

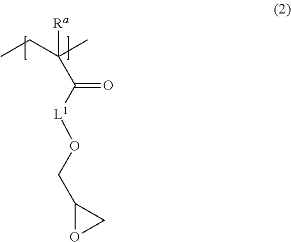

wherein,
R^{a} is hydrogen, or methyl; and
L¹ is absent, or is a C₁-C₁₀ alkylene or a C₁-C₁₀ oxyalkylene.

In one embodiment of the present invention, the repeating unit having a carbazole group may be included in an amount of 25 to 50 mol % based on 100 mol % of the total repeating units constituting the binder resin.

In one embodiment of the present invention, the repeating unit having a glycidyl group may be included in an amount of 10 to 30 mol % based on 100 mol % of the total repeating units constituting the binder resin.

In one embodiment of the present invention, the binder resin may be included in an amount of 10 to 30 wt % based on 100 wt % of the total thermosetting resin composition.

In one embodiment of the present invention, the thermal initiator may comprise one or more of compounds represented by the following formulae (3) to (5).

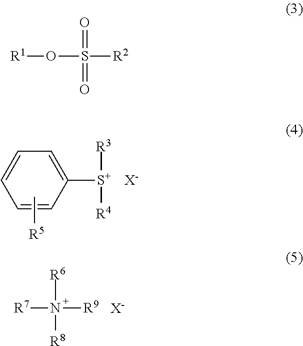

wherein,
R¹ is a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R² is a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R¹ and R² may each independently be substituted with halogen atom, cyano, nitro, carbonyl, sulfonic acid, —SO₃M, —CO₂M, hydroxy, formyl, amino, or a C₁-C₂₀ alkyl;
M represents a metal ion;
R³ and R⁴ are each independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R⁵ is hydrogen atom, halogen atom, hydroxyl, thioether, a C₁-C₃₀ alkyl, a C₂-C₃₀ alkenyl, a C₃-C₂₀ cycloalkyl, or a C₂-C₂₀ heterocycloalkyl;
R⁶ to R⁹ are each independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, a C₅-C₂₀ heteroaryl, or C₆-C₂₀ aralkyl;
X⁻ is PF₆⁻, AsF₆⁻, SbF₆⁻, (CF₃)₂PF₄⁻, (CF₃)₃PF₃⁻, (CF₃)₄PF₂⁻, (CF₃)₅PF⁻, (CF₃)₆P⁻, (C₂F₅SO₂)₂N⁻, (CF₃SO₃)₂N⁻, (CF₃SO₂)(CF₃CO)N⁻, CF₃CF₂(CF₃)₂CO⁻, (CF₃SO₂)₂CH⁻, (SF₅)₃C⁻, (CF₃SO₂)₃C⁻, CF₃COO⁻, CF₃SO₃⁻, (C₆F₅)₄B⁻, or C₃F₇COO⁻.

In one embodiment of the present invention, the thermal initiator may be included in an amount of 0.1 to 1.0 wt % based on 100 wt % of the total thermosetting resin composition.

In one embodiment of the present invention, the thermosetting agent may comprise an amine-based curing agent.

In one embodiment of the present invention, the thermosetting agent may comprise a compound represented by the following formula (6).

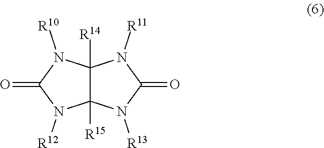

wherein,
R¹⁰ to R¹³ are each independently hydrogen, a C₁-C₄ alkyl, a C₁-C₄ alkoxy, a C₂-C₄ alkoxyalkyl, or thiol; and
R¹⁴ and R¹⁵ are each independently hydrogen, a C₁-C₄ alkyl, or an aryl.

In one embodiment of the present invention, the thermosetting agent may be included in an amount of 0.2 to 2.0 wt % based on 100 wt % of the total thermosetting resin composition.

In another aspect, the present invention provides a cured film formed from the thermosetting resin composition.

In one embodiment of the present invention, the cured film may be an overcoat film, a micro-lens, or an overcoat film with a micro-lens.

In yet another aspect, the present invention provides a solid-state imaging device comprising the above cured film.

### Advantageous Effects

The thermosetting resin composition according to the present invention can be cured within minutes at temperatures below 220° C. to form a cured film having high transmittance and high refractive index properties, excellent flatness and hardness, but no coating stains. In addition, the thermosetting resin composition according to the present invention has excellent stability over time, and properties favorable for implementation of micro-lens geometries, particularly dry etching resistance.

### BEST MODE

Hereinafter, the present invention will be described in more detail.

One embodiment of the present invention relates to a thermosetting resin composition comprising a binder resin (A), a thermal initiator (B), a thermosetting agent (C), and a solvent (D), in which the binder resin (A) comprises an acrylic copolymer comprising a repeating unit having a carbazole group and a repeating unit having a glycidyl group.

The thermosetting resin composition according to the present invention comprises an acrylic copolymer comprising a repeating unit having a carbazole group and a repeating unit having a glycidyl group as a binder resin, and a thermal initiator and a thermosetting agent, such that it can be cured within minutes at temperatures below 220° C. to form a cured film having high transmittance and high refractive index properties, excellent flatness and hardness, but no coating stains. Accordingly, it can be advantageously used in the manufacture of an organic protective film, i.e., an overcoat film that flattens the steps of a color filter used in an image sensor.

Furthermore, the thermosetting resin composition according to one embodiment of the present invention has excellent stability over time and dry etching resistance, which is advantageous for the realization of micro-lens shapes, by using a thermal initiator with a specific structure.

Conventionally, a micro-lens can be formed by forming a pattern using a photoresist on an overcoat film and then reflowing it at high heat to form a lens shape. However, when a cured film formed from a thermosetting resin composition according to one embodiment of the present invention is applied as an overcoat film to the lower part of the micro-lens, when the overcoat film is subjected to a dry etching process using gas after the reflow process, the upper micro-lens shape is transferred to the lower overcoat film, so that the overcoat film has a micro-lens shape and can simultaneously serve as a micro-lens.

### Binder Resin (A)

In one embodiment of the present invention, the binder resin (A) comprises an acrylic copolymer comprising a repeating unit having a carbazole group and a repeating unit having a glycidyl group.

The binder resin (A) comprises a repeating unit having a carbazole group and a repeating unit having a glycidyl group to increase the refractive index of the cured film, improve the hardness of the cured film, and increase the solubility, as well as improve the dry etching resistance.

The repeating unit having a carbazole group serves to increase the refractive index of the cured film.

The repeating unit having a carbazole group has a structure in which the carbazole group is introduced in the form of a pendant to the main chain.

Preferably, the repeating unit having a carbazole group may be represented by the following formula (1).

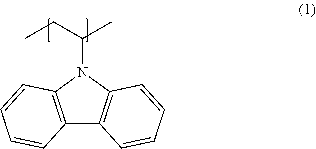

The repeating unit having a carbazole group may be introduced using vinyl carbazole or the like as monomers.

The repeating unit having a carbazole group may be included in an amount of 25 to 50 mol %, preferably 30 to 40 mol %, based on 100 mol % of the total repeating units constituting the binder resin. If the repeating unit having a carbazole group is included in less than 25 mol %, the refractive index of the cured film may be reduced, and if it is included in more than 50 mol %, the hardness of the cured film may be reduced.

The repeating unit having a glycidyl group serves to improve the hardness of the cured film and increase the solubility.

The repeating unit having a glycidyl group may have a structure in which the glycidyl group is introduced in the form of a pendant to the main chain.

Preferably, the repeating unit having a glycidyl group may be represented by the following formula (2).

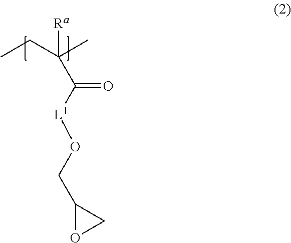

wherein,
R^{a} is hydrogen or methyl; and
L¹ is absent, or is a C₁-C₁₀ alkylene or a C₁-C₁₀ oxyalkylene.

The term “C₁-C₁₀ alkylene” as used herein means a straight or branched divalent hydrocarbon having 1 to 10 carbon atoms, and examples include, but are not limited to, methylene, ethylene, n-propylene, isopropylene, n-butylene, isobutylene, n-pentylene, n-hexylene, n-heptylene, n-octylene, n-nonylene, and the like.

The term “C₁-C₁₀ oxyalkylene” as used herein means a functional group having 1 to 10 carbon atoms in which one or more of the chain carbon atoms of a straight or branched divalent hydrocarbon is substituted with oxygen, and examples include, but are not limited to, oxymethylene, oxyethylene, oxypropylene, oxybutylene, oxypentylene, oxyhexylene, and the like.

The repeating unit having a glycidyl group may be introduced using (meth)acrylate having a glycidyl group as monomers, for example (oxiran-2-yl)methyl (meth)acrylate, and the like.

The repeating unit having a glycidyl group may be included in an amount of 10 to 30 mol %, preferably 15 to 25 mol %, based on 100 mol % of the total repeating units constituting the binder resin. If the repeating unit having a glycidyl group is included in less than 10 mol %, the hardness of the cured film may be reduced or the solubility may be reduced, and if it is included in more than 30 mol %, the refractive index of the cured film may be reduced.

The binder resin (A) may further comprise other repeating units other than the repeating unit having a carbazole group and the repeating unit having a glycidyl group described above.

The other repeating units may include a repeating unit having a carboxyl group, a repeating unit having a hydroxy group, a repeating unit having a C₁-C₁₀ alkyl group, a repeating unit having an aryl group, and the like. In particular, the other repeating units may further comprise at least one of the repeating unit having a hydroxy group and the repeating unit having an aryl group. The repeating unit having a hydroxy group can improve the hardness of the cured film and increase the solubility, and the repeating unit having an aryl group can increase the solubility.

The repeating unit having a carboxyl group may be introduced using an ethylenically unsaturated monomer having a carboxyl group.

Specific examples of the ethylenically unsaturated monomer having a carboxylic group include monocarboxylic acids such as acrylic acid, methacrylic acid, crotonic acid, and the like; dicarboxylic acids such as fumaric acid, mesaconic acid, itaconic acid, and the like; anhydrides of these dicarboxylic acids; mono(meth)acrylates of polymers having carboxylic and hydroxy groups at both ends, such as @-carboxypolycaprolactone mono(meth)acrylate, and the like. Among these, acrylic acid and methacrylic acid are preferred.

The repeating unit having a hydroxy group may be introduced using an ethylenically unsaturated monomer having a hydroxy group, or may be introduced by further reacting the repeating unit having a carboxyl group with a compound having a glycidyl group.

Examples of the ethylenically unsaturated monomer having a hydroxy group are 2-hydroxyethyl (meth)acrylate, 2-hydroxypropyl (meth)acrylate, 4-hydroxybutyl (meth)acrylate, 2-hydroxy-3-phenoxypropyl (meth)acrylate, N-hydroxyethyl acrylamide, and the like.

Examples of the compound having a glycidyl group include n-butylglycidyl ether, propylglycidyl ether, phenylglycidyl ether, 2-ethylhexylglycidyl ether, glycidylbutyrate, glycidylmethyl ether, ethylglycidyl ether, glycidylisopropyl ether, t-butylglycidyl ether, benzylglycidyl ether, glycidyl 4-t-butylbenzoate, glycidyl stearate, allyl glycidyl ether, methacrylic acid glycidyl ester, and the like, which may be used in combination of two or more.

The repeating unit having a C₁-C₁₀ alkyl group may be introduced using a C₁-C₁₀ alkyl (meth)acrylate compound, such as methyl (meth)acrylate, ethyl (meth)acrylate, n-propyl (meth)acrylate, i-propyl (meth)acrylate, n-butyl (meth)acrylate, i-butyl (meth)acrylate, sec-butyl (meth)acrylate, t-butyl (meth)acrylate, and the like, which may be used in combination of two or more.

The repeating unit having an aryl group may be introduced using an aromatic vinyl compound such as styrene, vinyltoluene, α-methylstyrene, p-chlorostyrene, o-methoxystyrene, m-methoxystyrene, p-methoxystyrene, o-vinylbenzylmethyl ether, m-vinylbenzylmethyl ether, p-vinylbenzylmethyl ether, o-vinylbenzylglycidyl ether, m-vinylbenzylglycidyl ether, p-vinylbenzylglycidyl ether, and the like; an aryl (meth)acrylate compound such as phenyl (meth)acrylate, benzyl (meth)acrylate, and the like, which may be used in combination of two or more.

Furthermore, the binder resin (A) may further comprise repeating units introduced using N-substituted maleimide-based compounds such as N-cyclohexylmaleimide, N-benzylmaleimide, N-phenylmaleimide, N-o-hydroxyphenylmaleimide, N-m-hydroxyphenylmaleimide, N-p-hydroxyphenylmaleimide, N-o-methylphenylmaleimide, N-m-methylphenylmaleimide, N-p-methylphenylmaleimide, N-o-methoxyphenylmaleimide, N-m-methoxyphenylmaleimide, N-p-methoxyphenylmaleimide, and the like; alicyclic (meth)acrylate compounds such as cyclopentyl (meth)acrylate, cyclohexyl (meth)acrylate, 2-methylcyclohexyl (meth)acrylate, 2-dicyclopentanyloxyethyl (meth)acrylate, isobornyl (meth)acrylate, and the like; unsaturated oxetane compounds such as 3-(methacryloyloxymethyl) oxetane, 3-(methacryloyloxymethyl)-3-ethyloxetane, 3-(methacryloyloxymethyl)-2-trifluoromethyloxetane, 3-(methacryloyloxymethyl)-2-phenyloxetane, 2-(methacryloyloxymethyl) oxetane, 2-(methacryloyloxymethyl)-4-trifluoromethyloxetane, and the like; carboxylic acid vinyl ester compounds such as vinyl acetate, vinyl propionate, and the like; and vinyl cyanide compounds such as (meth)acrylonitrile, α-chloroacrylonitrile, and the like.

The other repeating units may be included in residual amounts to bring the total mol % of the repeating units constituting the binder resin to 100 mol %.

The method of preparing the copolymer is not particularly limited, and any polymerization method known in the art may be used, and among the known polymerization methods, a solution polymerization method is preferred. Furthermore, the polymerization temperature or polymerization time depends on the type or ratio of monomers introduced, the molecular weight and the acid value of the desired alkali-soluble resin, but for example, the polymerization can be carried out at 60 to 130° C. for 1 to 10 hours.

If a solvent is used for the polymerization, a solvent used in conventional radical polymerization reactions can be used, and specifically, tetrahydrofuran, dioxane, ethylene glycol dimethyl ether, diethylene glycol dimethyl ether, acetone, methyl ethyl ketone, methyl isobutyl ketone, cyclohexanone, ethyl acetate, butyl acetate, propylene glycol monomethyl ether acetate, 3-methoxybutyl acetate, methanol, ethanol, propanol, n-butanol, ethylene glycol monomethyl ether, propylene glycol monomethyl ether, toluene, xylene, ethylbenzene, chloroform, dimethyl sulfoxide, and the like. These solvents can be used alone or in combination of two or more.

As a polymerization initiator used in the above polymerization, a commonly used polymerization initiator can be added, and is not particularly limited. Specific examples include organic peroxides such as diisopropylbenzene hydroperoxide, di-t-butylperoxide, benzoylperoxide, t-butylperoxyisopropylcarbonate, t-amylperoxy-2-ethylhexanoate, t-butylperoxy-2-ethylhexanoate, and the like; and nitrogenous compounds such as 2,2′-azobis(isobutyronitrile), 2,2′-azobis(2,4-dimethylvaleronitrile), dimethyl 2,2′-azobis(2-methylpropionate), and the like. These can be used alone or in combination of two or more.

During the polymerization, a chain transfer agent may be used to control the molecular weight or molecular weight distribution of the copolymer. As the chain transfer agent, mercapto compounds such as n-dodecanthiol, mercaptoacetic acid, methyl mercaptoacetic acid; α-methylstyrene dimer, and the like can be used.

The binder resin (A) may have a polystyrene equivalent weight average molecular weight (hereinafter simply referred to as “weight average molecular weight”) measured by gel permeation chromatography (GPC; tetrahydrofuran as elution solvent) of 5,000 to 30,000, preferably 10,000 to 20,000.

The molecular weight distribution [weight average molecular weight (Mw)/number average molecular weight (Mn)] of the binder resin (A) may be 1.0 to 6.0, preferably 1.3 to 4.0.

When the weight average molecular weight and molecular weight distribution of the binder resin (A) are in the above range, the coating film hardness is improved and the adhesion is excellent.

The binder resin (A) may be included in an amount of 10 to 30 wt %, preferably 15 to 25 wt %, based on 100 wt % of the total thermosetting resin composition. If the content of the binder resin is outside the above range, the flatness and hardness of the coating film may be deteriorated and stains may occur on the coating surface. Specifically, if the content of the binder resin is less than the above range, the relatively higher content of the solvent may result in a lower viscosity of the composition, which may result in a decrease in flatness and a decrease in refractive index, and if the content of the binder resin is more than the above range, the relatively lower content of the solvent may result in a decrease in flatness due to aggregation of the thermosetting agent.

### Thermal Initiator (B)

In one embodiment of the present invention, the thermal initiator (B) enables sufficient curing even at a low temperature curing process of 220° C. or less, preferably 180° C. or less, and serves to improve the adhesion and transmittance of the overcoat film (protective film) formed using it.

The thermal initiator (B) is a compound that generates an acid, such as a sulfonic acid, under the action of heat. The acid generated by the heat causes a curing reaction between the functional groups of the binder resin and the thermosetting agent. Furthermore, while acting as a thermal initiator, it does not affect the transmittance of the thermosetting resin composition, making it possible to form a cured film with a high transmittance.

The thermal initiator may comprise one or more of compounds represented by the following formulae (3) to (5).

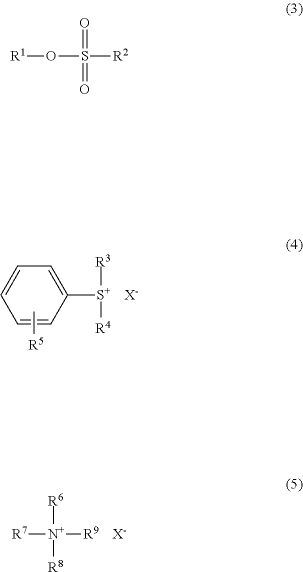

wherein,
R¹ is a C₁-C₃₀ alkyl, a C₂-C₃₀ alkenyl, a C₃-C₂₀ cycloalkyl, a C₂-C₂₀ heterocycloalkyl, a
C₆-C₂₀ aryl, or a C₅-C₂₀ heteroaryl;
R² is a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R¹ and R² may each independently be substituted with halogen atom, cyano, nitro, carbonyl, sulfonic acid, —SO₃M, —CO₂M, hydroxy, formyl, amino, or a C₁-C₂₀ alkyl;
M represents a metal ion;
R³ and R⁴ are each independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R⁵ is hydrogen atom, halogen atom, hydroxyl, thioether, a C₁-C₃₀ alkyl, a C₂-C₃₀ alkenyl, a C₃-C₂₀ cycloalkyl, or a C₂-C₂₀ heterocycloalkyl;
R⁶ to R⁹ are each independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, a C₅-C₂₀ heteroaryl, or C₆-C₂₀ aralkyl;
X⁻ is PF₆⁻, AsF₆⁻, SbF₆⁻, (CF₃)₂PF₄⁻, (CF₃)₃PF₃⁻, (CF₃)₄PF₂⁻, (CF₃)₅PF⁻, (CF₃)₆P⁻, (C₂F₅SO₂)₂N⁻, (CF₃SO₃)₂N⁻, (CF₃SO₂)(CF₃CO)N⁻, CF₃CF₂(CF₃)₂CO⁻, (CF₃SO₂)₂CH⁻, (SF₅)₃C⁻, (CF₃SO₂)₃C⁻, CF₃COO⁻, CF₃SO₃⁻, (C₆F₅)₄B⁻, or C₃F₇COO⁻.

The term “C₁-C₃₀ alkyl” as used herein means a straight or branched hydrocarbon having 1 to 30 carbon atoms, and examples include, but are not limited to, methyl, ethyl, n-propyl, i-propyl, n-butyl, i-butyl, t-butyl, pentyl, hexyl, 2-ethylhexyl, heptyl, 2-ethylheptyl, octyl, nonyl, decyl, undecyl, dodecyl, tridecyl, tetradecyl, pentadecyl, hexadecyl, heptadecyl, stearyl, nonadecyl, eicosanyl, behenyl, and the like.

The term “C₂-C₃₀ alkenyl” as used herein means a straight or branched unsaturated hydrocarbon composed of 2 to 30 carbon atoms having one or more carbon-carbon double bonds, and examples include, but are not limited to, ethylenyl, propenyl, butenyl, pentenyl, and the like.

The term “C₃-C₂₀ cycloalkyl” as used herein means a simple or fused cyclic hydrocarbon having 3 to 20 carbon atoms, and examples include, but are not limited to, cyclopropyl, cyclobutyl, cyclopentyl, cyclohexyl, and the like.

The term “C₂-C₂₀ heterocycloalkyl” as used herein means a functional group having 2 to 20 carbon atoms in which at least one of the ring carbons of a simple or fused cyclic hydrocarbon is substituted with oxygen, sulfur, or nitrogen, and examples include, but are not limited to, thiazolidinyl, oxiranyl, and the like.

The term “C₆-C₂₀ aryl” as used herein includes both monovalent aromatic groups and partially reduced derivatives thereof. The aromatic group is a simple or fused ring type composed of 6 to 20 carbon atoms. Examples of representative aryl groups include, but are not limited to, phenyl, naphthyl, tetrahydronaphthyl, pyrenyl, fluorenyl, diphenylfluorenyl, dinaphthalenylfluorenyl, carbazolyl, biphenyl, and the like.

The term “C₅-C₂₀ heteroaryl” as used herein includes both monovalent heteroaromatic groups and partially reduced derivatives thereof. The heteroaromatic group is a simple or fused ring type composed of 5 to 20 carbon atoms and contains at least one oxygen, sulfur, or nitrogen. Examples of representative heteroaryl groups include, but are not limited to, pyridinyl, furanyl, thiophenyl, indolyl, quinolinyl, imidazolinyl, oxazolyl, thiazolyl, and the like.

The term “C₁-C₂₀ alkyl” as used herein means a straight or branched monovalent hydrocarbon having 1 to 20 carbon atoms, and examples include, but are not limited to, methyl, ethyl, n-propyl, isopropyl, n-butyl, isobutyl, tert-butyl, sec-butyl, 1-methyl-butyl, 1-ethyl-butyl, n-pentyl, isopentyl, neopentyl, tert-pentyl, n-hexyl, 1-methylpentyl, 2-methylpentyl, 4-methyl-2-pentyl, 3,3-dimethylbutyl, 2-ethylbutyl, n-heptyl, 1-methylhexyl, n-octyl, tert-octyl, 1-methylheptyl, 2-ethylhexyl, 2-propylpentyl, n-nonyl, 2,2-dimethylheptyl, n-decyl, and the like.

As used herein, metal ions refer to alkali metal or alkaline earth metal ions.

As used herein, a thioether group refers to a group of the formula-SR, in which R is a C₁-C₃₀ alkyl or aryl, including but not limited to a methylthio group, an ethylthio group, and the like.

The term “C₆-C₂₀ aralkyl” as used herein means a complex group having 6 to 20 carbon atoms formed by bonding an aryl group (an aromatic hydrocarbon group) to a carbon atom of an alkyl group, and examples include, but are not limited to, benzyl, phenethyl, and the like.

Preferably, X⁻ is CF₃SO₃⁻.

The compounds represented by the above formulae (3) to (5) may have a decomposition initiation temperature of less than 200° C., for example, 100° C. or more and less than 200° C., preferably 150° C. or more and less than 180° C. Accordingly, sufficient curing can be achieved within a few minutes even at a relatively low temperature of 220° C. or below by using the compound represented by the above formulae (3) to (5) as a thermal initiator. Furthermore, the compounds represented by the above formulae (3) to (5) are also advantageous in terms of dry etch resistance.

In particular, the compound represented by the above formula (5) is reactive with the binder resin and/or thermosetting agent in the composition only to a degree that does not affect reliability, which is advantageous for achieving both stability over time and reliability.

For example, the compound represented by the above formula (3) may be one or more of compounds represented by the following formulae (3-1) to (3-3).

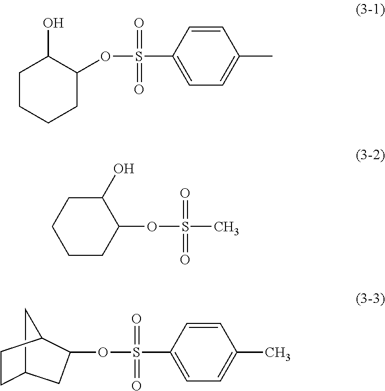 [SMILES: Cc1ccc(S(=O)(=O)OC2CCCCC2O)cc1 ; CS(=O)(=O)OC1CCCCC1O ; Cc1ccc(S(=O)(=O)OC2CC3CCC2C3)cc1]

Preferably, the compound represented by the above formula (4) can be a compound represented by the following formula (4a).

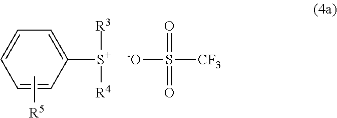

wherein,
R³ and R⁴ are independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl; and
R⁵ is hydrogen, halogen atom, hydroxyl, thioether, a C₁-C₃₀ alkyl, a C₂-C₃₀ alkenyl, a C₃-C₂₀ cycloalkyl, or a C₂-C₂₀ heterocycloalkyl.

For example, the compound represented by the above formula (4) may be (4-methylthiophenyl)methylphenylsulfonium trifluoromethanesulfonate, (4-hydroxyphenyl)dimethylsulfonium trifluoromethanesulfonate, diphenyl(4-hydroxyphenyl)sulfonium trifluoromethanesulfonate, methylphenyl(4-hydroxyphenyl)sulfonium trifluoromethanesulfonate, and the like.

Preferably, the compound represented by the above formula (5) may be a compound represented by the following formula (5a).

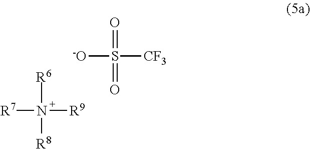

wherein,
R⁶ to R⁹ are independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, a C₅-C₂₀ heteroaryl, or a C₆-C₂₀ aralkyl.

Preferably, R⁶ and R⁷ may independently be a C₁-C₃₀ alkyl, R⁸ may be a C₆-C₂₀ aryl, and R⁹ may be a C₆-C₂₀ aralkyl.

For example, the compound represented by the above formula (5) may be a compound represented by the following formula (5-1).

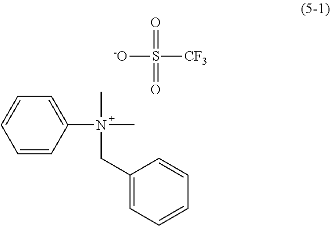

The thermal initiator may be included in an amount of 0.1 to 1.0 wt % based on 100 wt % of the total thermosetting resin composition. When the thermal initiator is included in the above range, the solubility in solvents is improved, and the thermosetting resin composition can be highly sensitized and the cured film can be formed to have good flatness.

### Thermosetting Agent (C)

In one embodiment of the present invention, the thermosetting agent (C) is a component that undergoes a curing reaction with a functional group of the binder resin.

An acid anhydride-based curing agent, an amine-based curing agent, a phenol-based curing agent, and the like can be used as the thermosetting agent, and an amine-based curing agent is preferred in terms of improving productivity, adhesion, and dry etching resistance.

The amine-based curing agent may include a compound derived from a glycoluril structure. The compound derived from the glycoluril structure may include a compound represented by the following formula (6).

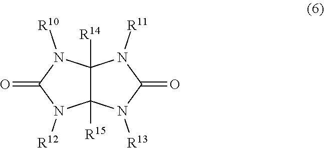

wherein,
R¹⁰ to R¹³ are each independently hydrogen, a C₁-C₄ alkyl, a C₁-C₄ alkoxy, a C₂-C₄ alkoxyalkyl, or thiol; and
R¹⁴ and R¹⁵ are each independently hydrogen, a C₁-C₄ alkyl, or an aryl.

The term “C₁-C₄ alkyl” as used herein means a straight or branched monovalent hydrocarbon having 1 to 4 carbon atoms, and examples include, but are not limited to, methyl, ethyl, n-propyl, i-propyl, n-butyl, i-butyl, t-butyl, and the like.

The term “C₁-C₄ alkoxy” as used herein means a straight or branched alkoxy group having 1 to 4 carbon atoms, and examples include, but are not limited to, methoxy, ethoxy, n-propanoxy, and the like.

The term “C₂-C₄ alkoxyalkyl” as used herein means a complex group having 2 to 4 carbon atoms formed by bonding a straight or branched alkoxy group to a carbon atom of an alkyl group, and examples include, but are not limited to, methoxymethyl, ethoxymethyl, methoxyethyl, and the like.

As used herein, aryl groups include both aromatic and heteroaromatic groups and their partially reduced derivatives. An aromatic group is a simple or fused ring type composed of 5 to 15 carbon atoms, and a heteroaromatic group is an aromatic group containing at least one oxygen, sulfur, or nitrogen. Examples of representative aryl groups include, but are not limited to, phenyl, naphthyl, pyridinyl, furanyl, thiophenyl, indolyl, quinolinyl, imidazolinyl, oxazolyl, thiazolyl, tetrahydronaphthyl, and the like.

Preferably, the compound represented by the above formula (6) can be one or more of compounds represented by the following formulae (6-1) to (6-4).

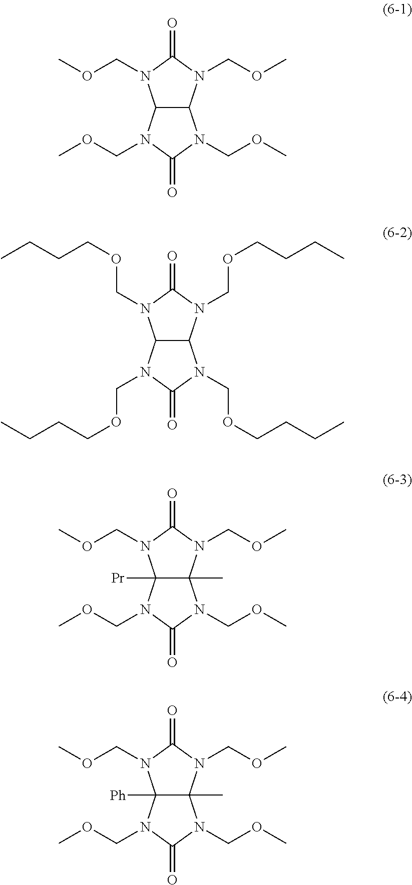

wherein,
Pr is propyl; and
Ph is phenyl.

The compound represented by the above formula (6) can undergo a curing reaction with the binder resin during post-bake to improve stability. Furthermore, the compound represented by the above formula (6) is located in the space between the binder resins and then cured, so that the space between the binder resins can be kept constant, and since N reacts with acid, the staining caused by acid can be suppressed to improve the transmittance.

The thermosetting agent may be included in an amount of 0.2 to 2.0 wt %, based on 100 wt % of the total thermosetting resin composition. When the thermosetting agent is included in the above range, the effect of improving the transmittance is maximized and a cured film with good adhesion can be formed.

### Solvent (D)

The solvent (D) is not particularly limited and various organic solvents used in the relevant technical field can be used.

Specific examples of the solvent (D) include, but are not limited to, ethylene glycol monoalkyl ethers, such as ethylene glycol monomethyl ether, ethylene glycol monoethyl ether, ethylene glycol monopropyl ether, and ethylene glycol monobutyl ether; diethylene glycol dialkyl ethers, such as diethylene glycol dimethyl ether, diethylene glycol diethyl ether, diethylene glycol ethyl methyl ether, diethylene glycol dipropyl ether, diethylene glycol dibutyl ether, and the like; ethylene glycol alkyl ether acetates, such as methylcellosolve acetate, ethylcellosolve acetate, ethylene glycol monobutyl ether acetate, ethylene glycol monoethyl ether acetate, and the like; alkylene glycol alkyl ether acetates, such as propylene glycol monomethyl ether acetate, propylene glycol monoethyl ether acetate, propylene glycol monopropyl ether acetate, methoxybutyl acetate, methoxypentyl acetate, and the like; propylene glycol monoalkyl ethers, such as propylene glycol monomethyl ether, propylene glycol monoethyl ether, propylene glycol monopropyl ether, propylene glycol monobutyl ether, and the like; propylene glycol dialkyl ethers, such as propylene glycol dimethyl ether, propylene glycol diethyl ether, propylene glycol ethyl methyl ether, propylene glycol dipropyl ether, propylene glycol propyl methyl ether, propylene glycol ethyl propyl ether, and the like; propylene glycol alkyl ether propionates, such as propylene glycol methyl ether propionate, propylene glycol ethyl ether propionate, propylene glycol propyl ether propionate, propylene glycol butyl ether propionate, and the like; butyldiolmonoalkyl ethers, such as methoxybutyl alcohol, ethoxybutyl alcohol, propoxybutyl alcohol, butoxybutyl alcohol, and the like; butanediolmonoalkyl ether acetates, such as methoxybutyl acetate, ethoxybutyl acetates, propoxybutyl acetate, butoxybutyl acetate, and the like; butanediolmonoalkyl ether propionates, such as methoxybutyl propionate, ethoxybutyl propionate, propoxybutyl propionate, butoxybutyl propionate, and the like; dipropylene glycol dialkyl ethers, such as dipropylene glycol dimethyl ether, dipropylene glycol diethyl ether, dipropylene glycol methyl ethyl ether, and the like; aromatic hydrocarbons, such as benzene, toluene, xylene, mesitylene, and the like; ketones, such as methylethyl ketone, acetone, methylamyl ketone, methylisobutyl ketone, cyclohexanone, and the like; alcohols, such as ethanol, propanol, butanol, hexanol, cyclohexanol, ethylene glycol, glycerin, and the like; esters, such as methyl acetate, ethyl acetate, propyl acetate, butyl acetate, ethyl 2-hydroxypropionate, methyl 2-hydroxy-2-methylpropionate, ethyl 2-hydroxy-2-methylpropionate, methyl hydroxyacetate, ethyl hydroxyacetate, butyl hydroxyacetate, methyl lactate, ethyl lactate, propyl lactate, butyl lactate, methyl 3-hydroxypropionate, ethyl 3-hydroxypropionate, propyl 3-hydroxypropionate, butyl 3-hydroxypropionate, methyl 2-hydroxy-3-methylbutanoate, methyl methoxyacetate, ethyl methoxyacetate, propyl methoxyacetate, butyl methoxyacetate, methyl ethoxyacetate, ethyl ethoxyacetate, propyl ethoxyacetate, butyl ethoxyacetate, methyl propoxyacetate, ethyl propoxyacetate, propyl propoxyacetate, butyl propoxyacetate, methyl butoxyacetate, ethyl butoxyacetate, propyl butoxyacetate, butyl butoxyacetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, butyl 3-butoxypropionate, and the like; cyclic ethers, such as tetrahydrofuran, pyran, and the like; cyclic esters such as γ-butyrolactone, and the like. The solvents (D) exemplified herein can be used alone or in a mixture of two or more.

The solvent (D) may preferably be diethylene glycol dialkyl ethers, alkylene glycol alkyl ether acetates, ketones, butanediol alkyl ether acetates, butanediol monoalkyl ethers, esters such as ethyl 3-ethoxypropionate, methyl 3-methoxypropionate, and the like, considering the applicability and dryness. More preferably, diethylene glycol ethyl methyl ether, propylene glycol monomethyl ether acetate, propylene glycol monoethyl ether acetate, cyclohexanone, methoxybutyl acetate, methoxybutanol, 3-ethoxypropionic acid ethyl, 3-methoxypropionic acid methyl, and the like may be used.

The content of the solvent (D) may be at least 70 wt %, preferably 75 to 85 wt %, based on 100 wt % of the total thermosetting resin composition. If the content of the solvent (D) is less than 70 wt %, the viscosity of the composition is high, which deteriorates the coatability, the staining phenomenon may be reproduced after coating, and the flatness may be poor, resulting in a problem that the thermosetting resin composition is not uniformly applied.

### Additives (E)

A thermosetting resin composition according to one embodiment of the present invention may contain, in addition to the above ingredients, additives known in the art without impairing the effectiveness of the invention.

For example, surfactants may be used to improve wettability, applicability, and leveling.

Surfactants include silicone-based and fluorine-based surfactants, and commercially available products include Florinate FC430 and Florinate FC431 manufactured by Sumitomo 3M; Megafac F142D, Megafac F171, Megafac F172, Megafac F173, Megafac F177, Megafac, F183, Megafac R30, Megafac R08, Megafac R09, Megafac BL20, Megafac 475, Megafac 489, Megafac 544, and Megafac F443, manufactured by Dai Nippon Ink Chemical Corporation; F-430, F 510, F-554, F-563, R-40, R-41, and R-43, manufactured by DIC, and the like.

The surfactant may be included in an amount of 0.001 to 1.0 wt %, preferably from 0.005 to 0.1 wt %, based on 100 wt % of the total thermosetting resin composition.

A thermosetting resin composition of the present invention may be prepared, for example, by a method of adding and mixing a binder resin (A), a thermal initiator (B), a thermosetting agent (C), and other additives (E) used as needed to a solvent (D). However, the present invention is not limited to such methods.

The thermosetting resin composition prepared as described above can be used after being filtered using a filter or the like having a pore diameter of 0.1 to 5 μm.

One embodiment of the present invention relates to a cured film formed from the above-described thermosetting resin composition.

According to the present invention, the cured film can be produced by applying the above-described thermosetting resin composition to a substrate and then applying heat.

In a preferred example of the manufacturing process, the thermosetting resin composition is applied to a substrate (usually glass) or a layer composed of a solid portion of the resin composition formed first, and then heated and dried to remove volatile components such as solvents to obtain a smooth film.

The application method can be carried out, for example, by spin coat, flexible application, roll application, slit and spin coat, or slit coat method.

After application, the desired cured film can be obtained by heating and curing the film for a few minutes (approximately within 3 minutes) at a temperature of 220° C. or less, preferably 180° C. or less, such as 100 to 180° C.

The cured film thus obtained is useful as an organic protective film, i.e., an overcoat film, to flatten the steps of a color filter used in an image sensor such as a CMOS image sensor.

Furthermore, the cured film can also serve as a micro-lens of a solid-state imaging device. That is, the cured film can be an overcoat film with a micro-lens.

Specifically, a photoresist (PR) may be applied to the cured film, dried to obtain a coating film, exposed and developed to form a pattern, and then heated to reflow the pattern to form a micro-lens pattern, and then the shape of the micro-lens pattern may be transferred to the cured film by etching back the cured film located at the bottom using the micro-lens pattern as an etching mask. Thus, as the cured film has the shape of a micro-lens, it can simultaneously perform the role of a micro-lens.

The thickness of the cured film may be 0.01 to 100 μm, preferably 0.05 to 10 μm, more preferably from 0.1 to 3 μm, and even more preferably from 0.2 to 1.5 μm.

Thus, one embodiment of the present invention relates to a solid-state imaging device comprising the cured film as described above.

The solid-state imaging device includes a support comprising a semiconductor element or a photoelectric conversion element and a micro-lens, and a color filter may be disposed between the support and the micro-lens.

Hereinafter, the present invention will be described more specifically by means of examples, comparative examples, and experimental examples. These examples, comparative examples, and experimental examples are intended to illustrate the present invention only, and it is obvious to those skilled in the art that the scope of the present invention is not limited to them.

### Examples and Comparative Examples: Preparation of Thermosetting Resin Compositions

Thermosetting resin compositions were prepared by mixing the respective components in the composition of Table 1 and Table 2 below and filtering through a millipore filter with a pore diameter of 0.2 μm (unit: weight %).

TABLE 1

| | Example | Example | Example | Example | Example | Example | Example |
|---|---|---|---|---|---|---|---|
| | 1 | 2 | 3 | 4 | 5 | 6 | 7 |
| (A-1) Acrylic resin | 19.5 | 19.5 | 21 | 21 | 10 | 30 | 19.5 |
| (B-1) Thermal | 0.1 | 0.2 | 0.1 | 0.2 | 0.2 | 0.2 | |
| initiator | | | | | | | |
| (B-2) Thermal | | | | | | | 0.1 |
| initiator | | | | | | | |
| (C) Thermosetting | 0.2 | 0.6 | 0.2 | 0.6 | 0.6 | 0.6 | 0.2 |
| agent | | | | | | | |
| (D-1) Solvent | 16 | 16 | 16 | 16 | 16 | 16 | 16 |
| (D-2) Solvent | 64.15 | 63.65 | 62.65 | 62.15 | 73.15 | 53.15 | 64.15 |
| (E) Additive | 0.05 | 0.05 | 0.05 | 0.05 | 0.05 | 0.05 | 0.05 |

TABLE 2

| | Comparative | Comparative | Comparative | Comparative |
|---|---|---|---|---|
| | Example 1 | Example 2 | Example 3 | Example 4 |
| (A-1) Acrylic resin | 19.5 | 19.5 | | |
| (A-2) Acrylic resin | | | 19.5 | |
| (A-3) Acrylic resin | | | | 19.5 |
| (B-1) Thermal initiator | 0.2 | | 0.2 | |
| (B-2) Thermal initiator | | | | 0.2 |
| (C) Thermosetting agent | | 0.6 | 0.6 | 0.6 |
| (D-1) Solvent | 16 | 16 | 16 | 16 |
| (D-2) Solvent | 64.25 | 63.85 | 63.65 | 63.65 |
| (E) Additive | 0.05 | 0.05 | 0.05 | 0.05 |

(A-1) Binder resin: acrylic resin obtained by copolymerization of 0.38 mol of vinyl carbazole, 0.11 mol of 2-hydroxyethyl acrylate, 0.21 mol of glycidyl acrylate, and 0.30 mol of styrene, weight average molecular weight (Mw): 16,000
(A-2) Binder resin: acrylic resin obtained by copolymerization of 0.32 mol of vinyl carbazole, 0.28 mol of 2-hydroxyethyl acrylate and 0.4 mol of styrene, weight average molecular weight (Mw): 14,000
(A-3) Binder resin: acrylic resin obtained by copolymerization of 0.3 mol of 2-hydroxyethyl acrylate, 0.3 mol of glycidyl acrylate, and 0.4 mol of styrene, weight average molecular weight (Mw): 3,700
(B-1) Thermal initiator: a compound of the following formula (3-1)

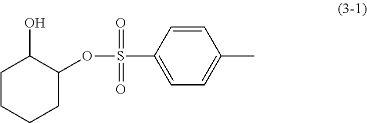 [SMILES: Cc1ccc(S(=O)(=O)OC2CCCCC2O)cc1]

(B-2) Thermal initiator: a compound of the following formula (5-1)

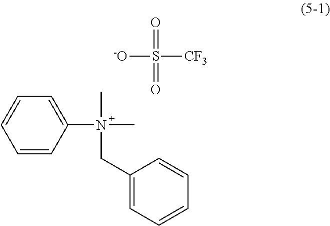

(C) Thermosetting agent: a compound of the following formula (6-3)

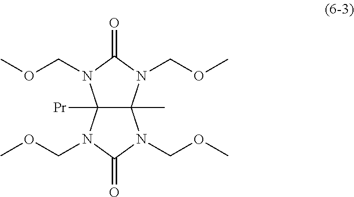

(D-1) Solvent: 3-methoxybutanol
(D-2) Solvent: propylene glycol methyl ether acetate
(E) Additive: surfactant, R-40 (DIC), 10% dilution

### Experimental Examples

Using the thermosetting resin compositions prepared in the above examples and comparative examples, cured films were prepared as follows, and the properties of the thermosetting resin composition and the cured film were evaluated by the following methods, and the results are shown in Table 3 and Table 4 below.

### <Preparation of Cured Film>

Approximately 2 ml of the thermosetting resin composition was applied onto a silicon wafer and a coating film was formed using a spin coater. The coating RPM was adjusted to target a coating film thickness of 1.2 μm, and curing was completed on a hot plate at 180° C. for 180 seconds.

### (1) Film Thickness

Three points were measured on a 6-inch silicon wafer and averaged, and the average value was used as the film thickness. The film thickness meter was VM-1210 (DAINIPPON).

### (2) Flatness

Based on a 6-inch silicon wafer, the film thickness was measured at 61 points to obtain the flatness and evaluated according to the following evaluation criteria. Filmetrics F-54 equipment was used to measure the film thickness.

### <Evaluation Criteria>

◯: Less than 1%
Δ: 1% or more but less than 2%
x: 2% or more

### (3) Transmittance

After forming the cured film in the same manner as the cured film preparation method above, except that a glass substrate was used instead of a silicon wafer, the transmittance was measured for wavelengths from 200 nm to 800 nm using a transmittance meter (Spectrophotometer, UV-2450) and averaged in the visible light region (400~700 nm).

### (4) Coating Stains

The surface of the cured film was observed with the naked eye and optical microscope and marked with ◯ if there were no surface stains and X if there were.

### (5) Refractive Index

Three points were measured using an Ellipsometer (Woollam, M-2000) and the average was taken.

### (6) Pencil Hardness

The hardness was measured from 3H to 4B using a motorized pencil hardness tester based on the ISO15184 evaluation method.

### (7) Stability Over Time

The initial film thickness was measured using the thermosetting resin compositions prepared in the above examples and comparative examples, and the stability over time was evaluated according to the following evaluation criteria by measuring the change in film thickness on a weekly basis while the compositions were stored at room temperature (23~25° C.).

Specifically, the film thickness was measured using a film thickness meter VM-1210 (DAINIPPON) after each composition was dropped onto a wafer in an amount of 1.8 μl, spin-coated at 1,800 rpm, and cured.

### <Evaluation Criteria>

◯: No change in film thickness compared to initial film thickness for more than three months
Δ: Change in film thickness from initial film thickness within a period of more than one month but less than three months
x: Change in film thickness from initial film thickness within a period of less than one month

### (8) Dry Etching Resistance

The thermosetting resin compositions prepared in the above examples and comparative examples were spin-coated on silicon wafers to a thickness of 1.2 μm after drying, and then cured at 220° C. for 180 seconds to prepare cured films, i.e., overcoat films.

A micro-lens photoresist was spin-coated on the overcoat film to a thickness of 0.5 μm after drying, cured at 100° C. for 90 seconds, and then exposed and developed to form a pattern. The pattern was heat treated at 146° C. for 300 seconds to perform a reflow process to obtain a micro-lens shaped pattern.

For the above micro-lens shaped pattern, dry etching was performed at 15° C. using a NeoGENII-MAXIS200 (Gigalain) as a dry etching device and C₄F₈, O₂, and Ar as etching gases at the following flow rates to measure the dry etching rate.

The dry etching resistance was evaluated according to the following evaluation criteria.

### <Etching Gas Flow Rate>

C₄F₈: 35 sccm
O₂: 60 sccm
Ar: 200 sccm

### <Evaluation Criteria>

◯: Less than 40 Å/sec
Δ: 40 Å/sec or more but less than 50 Å/sec
x: 50 Å/sec or more

TABLE 3

| | Example | Example | Example | Example | Example | Example | Example |
|---|---|---|---|---|---|---|---|
| | 1 | 2 | 3 | 4 | 5 | 6 | 7 |
| Film | 1.2 | 1.2 | 1.2 | 1.2 | 1.2 | 1.2 | 1.2 |
| thickness | | | | | | | |
| (μm) | | | | | | | |
| Flatness | ∘ | ∘ | ∘ | ∘ | Δ | Δ | ∘ |
| Transmittance | 99.9 | 99.7 | 99.6 | 99.4 | 99.3 | 99.3 | 99.8 |
| Coating | ∘ | ∘ | ∘ | ∘ | ∘ | ∘ | ∘ |
| stains | | | | | | | |
| Refractive | 1.58 | 1.58 | 1.59 | 1.59 | 1.56 | 1.60 | 1.58 |
| index | | | | | | | |
| Pencil | 1H | 2H | 2H | 2H | H | H | 2H |
| hardness | | | | | | | |
| Stability | Δ | Δ | Δ | Δ | Δ | Δ | ∘ |
| over time | | | | | | | |
| Dry | ∘ | ∘ | ∘ | ∘ | Δ | Δ | ∘ |
| etching | | | | | | | |
| resistance | | | | | | | |

TABLE 4

| | Comparative | Comparative | Comparative | Comparative |
|---|---|---|---|---|
| | Example 1 | Example 2 | Example 3 | Example 4 |
| Film thickness (μm) | 1.2 | 1.2 | 1.2 | 1.2 |
| Flatness | ∘ | x | x | ∘ |
| Transmittance | 99.2 | 99.1 | 98.8 | 99.3 |
| Coating stains | ∘ | x | x | ∘ |
| Refractive index | 1.56 | 1.56 | 1.60 | 1.52 |
| Pencil hardness | 1B | HB | HB | 1H |
| Stability over time | x | Δ | x | ∘ |
| Dry etching | x | x | x | Δ |
| resistance | | | | |

As shown in Table 3 and Table 4 above, the thermosetting resin compositions of Examples 1 to 7, which include an acrylic-based copolymer comprising a repeating unit having a carbazole group and a repeating unit having a glycidyl group as a binder resin according to the present invention, and which include a thermal initiator and a thermosetting agent, are capable of curing in a few minutes at a temperature of 220° C. or lower and forming a cured film having high transmittance and high refractive index properties, excellent flatness and hardness, and no coating stains.

In particular, the thermosetting resin composition of Example 7, which includes a compound represented by formula (5) as a thermal initiator, has been shown to have excellent stability over time and dry etching resistance suitable for the realization of micro-lens shapes.

On the other hand, the thermosetting resin compositions of Comparative Examples 1 to 4, which do not include an acrylic-based copolymer comprising a repeating unit having a carbazole group and a repeating unit having a glycidyl group as a binder resin, or do not include a thermal initiator or thermosetting agent, were found to have poor transmittance and/or refractive index, or to be difficult to simultaneously secure flatness, hardness, coating stain properties, stability over time, and dry etching resistance.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A thermosetting resin composition comprising a binder resin, a thermal initiator, a thermosetting agent, and a solvent,
wherein the binder resin comprises an acrylic copolymer comprising a repeating unit having a carbazole group and a repeating unit having a glycidyl group.

2. The thermosetting resin composition according to claim 1, wherein the repeating unit having a carbazole group is represented by formula (1):

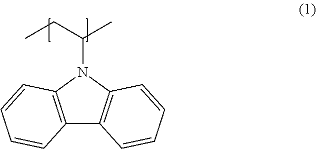

3. The thermosetting resin composition according to claim 1, wherein the repeating unit having a glycidyl group is represented by formula (2): 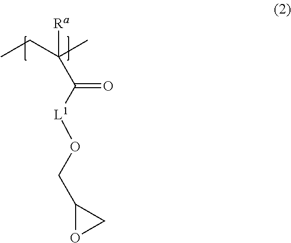
wherein,
R^{a} is hydrogen, or methyl; and
L¹ is absent, or is a C₁-C₁₀ alkylene or a C₁-C₁₀ oxyalkylene.

4. The thermosetting resin composition according to claim 1, wherein the repeating unit having a carbazole group is included in an amount of 25 to 50 mol % based on 100 mol % of the total repeating units constituting the binder resin.

5. The thermosetting resin composition according to claim 1, wherein the repeating unit having a glycidyl group is included in an amount of 10 to 30 mol % based on 100 mol % of the total repeating units constituting the binder resin.

6. The thermosetting resin composition according to claim 1, wherein the binder resin is included in an amount of 10 to 30 wt % based on 100 wt % of the total thermosetting resin composition.

7. The thermosetting resin composition according to claim 1, wherein the thermal initiator comprises one or more of compounds represented by formulae (3) to (5): 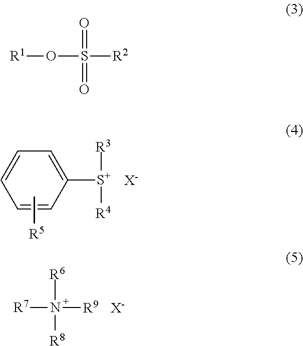
wherein,
R¹ is a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R² is a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R¹ and R² may each independently be substituted with halogen atom, cyano, nitro, carbonyl, sulfonic acid, —SO₃M, —CO₂M, hydroxy, formyl, amino, or a C₁-C₂₀ alkyl;
M represents a metal ion;
R³ and R⁴ are each independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, or a C₅-C₂₀ heteroaryl;
R⁵ is hydrogen atom, halogen atom, hydroxyl, thioether, a C₁-C₃₀ alkyl, a C₂-C₃₀ alkenyl, a C₃-C₂₀ cycloalkyl, or a C₂-C₂₀ heterocycloalkyl;
R⁶ to R⁹ are each independently a C₁-C₃₀ alkyl, a C₂-C₃₀ alkenyl, a C₃-C₂₀ cycloalkyl, a C₂-C₂₀ heterocycloalkyl, a C₆-C₂₀ aryl, a C₅-C₂₀ heteroaryl, or C₆-C₂₀ aralkyl;
X⁻ is PF₆⁻, AsF₆⁻, SbF₆⁻, (CF₃)₂PF₄⁻, (CF₃)₃PF₃⁻, (CF₃)₄PF₂⁻, (CF₃)₅PF⁻, (CF₃)₆P⁻, (C₂F₅SO₂)₂N⁻, (CF₃SO₃)₂N⁻, (CF₃SO₂)(CF₃CO)N⁻, CF₃CF₂(CF₃)₂CO⁻, (CF₃SO₂)₂CH⁻, (SF₅)₃C⁻, (CF₃SO₂)₃C⁻, CF₃COO⁻, CF₃SO₃⁻, (C₆F₅)₄B⁻, or C₃F₇COO⁻.

8. The thermosetting resin composition according to claim 1, wherein the thermal initiator is included in an amount of 0.1 to 1.0 wt % based on 100 wt % of the total thermosetting resin composition.

9. The thermosetting resin composition according to claim 1, wherein the thermosetting agent comprises an amine-based curing agent.

10. The thermosetting resin composition according to claim 9, wherein the thermosetting agent comprises a compound represented by formula (6): 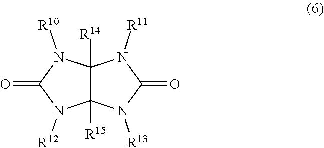
wherein,
R¹⁰ to R¹³ are each independently hydrogen, a C₁-C₄ alkyl, a C₁-C₄ alkoxy, a C₂-C₄ alkoxyalkyl, or thiol; and
R¹⁴ and R¹⁵ are each independently hydrogen, a C₁-C₄ alkyl, or an aryl.

11. The thermosetting resin composition according to claim 1, wherein the thermosetting agent is included in an amount of 0.2 to 2.0 wt % based on 100 wt % of the total thermosetting resin composition.

12. A cured film formed from the thermosetting resin composition according to claim 1.

13. The cured film according to claim 12, wherein the cured film is an overcoat film, a micro-lens, or an overcoat film with a micro-lens.

14. A solid-state imaging device comprising the cured film according to claim 12.
